(19) United States
(12) Patent Application Publication
(10) Pub. No.: US 2025/0261523 A1
(43) Pub. Date: Aug. 14, 2025

(54) DISPLAY APPARATUS

(71) Applicant: LG Display Co., Ltd., Seoul (KR)

(72) Inventor: Minwoo NAM, Paju-si (KR)

(73) Assignee: LG Display Co., Ltd., Seoul (KR)

(21) Appl. No.: 18/949,180

(22) Filed: Nov. 15, 2024

(30) Foreign Application Priority Data
Feb. 14, 2024 (KR) 10-2024-0020787

(51) Int. Cl. H10K 59/124; H10K 59/80

(52) U.S. Cl. CPC H10K 59/124; H10K 59/80516

(57) ABSTRACT

A display device includes a substrate; a first overcoat layer on the substrate; a second overcoat layer on the first overcoat layer, the second overcoat layer defining at least one open area at which the second overcoat layer is absent; an anode electrode on the second overcoat layer; an organic layer on the first overcoat layer, the second overcoat layer, and the anode electrode; and an auxiliary electrode in the at least one open area and on the first overcoat layer to be between the first overcoat layer and the organic layer, wherein the auxiliary electrode has an upper surface larger than or equal to a lower surface of the auxiliary electrode.

### CROSS REFERENCE TO RELATED APPLICATION

This application claims priority from Korean Patent Application No. 10-2024-0020787, filed on Feb. 14, 2024, which is hereby incorporated by reference for all purposes as if fully set forth herein.

### BACKGROUND

### Technical Field

The present disclosure relates to a display device.

### Discussion of the Related Art

As technology has advanced, a display device for displaying image have become more integrated and thinner.

A display device may include a display panel including various elements, transistors, etc. to display images. The display panel may include a plurality of subpixels which implement different colors to display an image.

In this case, as display devices become more integrated, multiple subpixels may be arranged more densely, so the gap between adjacent subpixels may become narrow. Further, if the gap between adjacent subpixels becomes narrow, interference may occur between subpixels, and thus, it may be difficult to independently control the light emitted from the subpixels.

### SUMMARY

Accordingly, embodiments of the present disclosure are directed to a display device that substantially obviates one or more of the problems due to limitations and disadvantages of the related art.

An aspect of the present disclosure is to provide a display device capable of blocking, or at least reducing, leakage current flowing between adjacent subpixels.

Another aspect of the present disclosure is to provide a display device capable of enabling low power consumption by preventing unnecessary power consumption.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display device may comprise a substrate; a first overcoat layer on the substrate; a second overcoat layer on the first overcoat layer, the second overcoat layer defining at least one open area at which the second overcoat layer is absent; an anode electrode on the second overcoat layer; an organic layer on the first overcoat layer, the second overcoat layer, and the anode electrode; and an auxiliary electrode in the at least one open area and on the first overcoat layer to be between the first overcoat layer and the organic layer, wherein the auxiliary electrode has an upper surface larger than or equal to a lower surface of the auxiliary electrode.

In another aspect, a display device, including at least a first subpixel and a second subpixel, may comprises a substrate; a first overcoat layer on the substrate; a second overcoat layer on at least a portion of the first overcoat layer; a first anode electrode on the second overcoat layer and overlapping the first subpixel; a second anode electrode on the second overcoat layer and overlapping the second subpixel; an organic layer on the first overcoat layer, the second overcoat layer, the first anode electrode, and the second anode electrode; and an auxiliary electrode on the first overcoat layer between the first overcoat layer and the organic layer, and in a plan view, between the first anode electrode and the second anode electrode, wherein a first angle between the substrate and a side surface of the auxiliary electrode is different than a second angle between the substrate and a side surface of at least one of the first anode electrode or second anode electrode.

In another aspect, a display device may comprise a substrate; a first overcoat layer on the substrate; a second overcoat layer on the first overcoat layer, the second overcoat layer defining at least one open area at which the second overcoat layer is absent; an auxiliary electrode on the first overcoat layer and in the at least one open area; and an organic layer on the auxiliary electrode, at least a portion of the organic layer contacting both side surfaces of the auxiliary electrode.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles.

FIG. 1 illustrates an example of the structure of a display device and a circuit structure included in a subpixel according to embodiments of the present disclosure.

FIG. 2 illustrates an example of a planar structure of a subpixel.

FIG. 3 illustrates an example of the cross-sectional structure of portion II′ of FIG. 2.

FIG. 4 illustrates an example of the organic layer shown in FIG. 3.

FIG. 5 illustrates another example of a planar structure of a subpixel.

FIG. 6 illustrates an example of the cross-sectional structure of portion II-II′ of FIG. 5.

FIG. 7 is an enlarged view of part A of FIG. 6.

FIG. 8 illustrates another example of the cross-sectional structure of portion II-II′ of FIG. 5.

FIG. 9 is an enlarged view of part B of FIG. 8.

FIG. 10 illustrates an example of a planar structure of a display panel according to embodiments of the present disclosure.

FIG. 11 illustrates an example of the cross-sectional structure of portion III-III′ of FIG. 10.

FIGS. 12A to 12E illustrate examples of methods for manufacturing a display device according to embodiments of the present disclosure.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms, such as “including,” “having,” “containing,” “constituting” “make up of,” and “formed of” used herein, are generally intended to allow other components to be added unless the terms are used with the term “only.” As used herein, singular forms are intended to include plural forms unless the context clearly indicates otherwise.

Terms, such as “first,” “second,” “A,” “B,” “(A),” or “(B)” may be used herein to describe elements of the present disclosure. Each of these terms is not used to define essence, order, sequence, or number of elements etc., but is used merely to distinguish the corresponding element from other elements.

When it is mentioned that a first element “is connected or coupled to,” “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to,” “contact or overlap,” etc. each other via a fourth element. Here, the second element may be included in at least one of two or more elements that “are connected or coupled to,” “contact or overlap,” etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can.”

Hereinafter, embodiments will be described in detail with reference to the accompanying drawings.

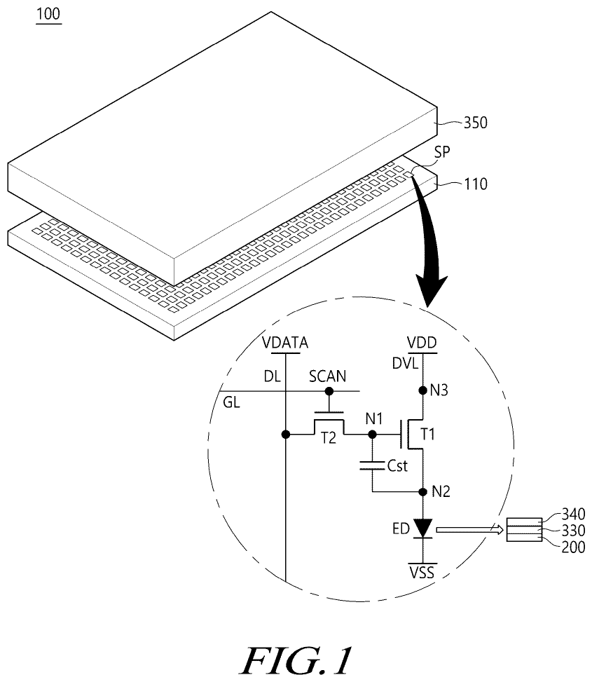

FIG. 1 illustrates an example of the structure of a display device and a circuit structure included in a subpixel according to embodiments of the present disclosure.

With reference to FIG. 1, a plurality of subpixels SP may be disposed in a display area of a display panel 110 included in a display device 100.

Each of the plurality of subpixels SP may include a light emitting device ED and a subpixel circuit unit configured to drive the light emitting device ED.

The subpixel circuit unit may include a driving transistor T1 for driving the light emitting device ED, a scan transistor T2 for transferring the data voltage VDATA to a first node N1 of the driving transistor T1, and a storage capacitor Cst for maintaining a constant voltage during one frame.

The driving transistor T1 may include a first node N1 to which a data voltage is applied, a second node N2 electrically connected to the light emitting device ED, and a third node N3 to which the driving voltage VDD is applied from a driving voltage line DVL. In the driving transistor T1, the first node N1 may be a gate node, the second node N2 may be a source node or a drain node, and the third node N3 may be a drain node or a source node. Hereinafter, for convenience of explanation, there illustrates a case in which the first node N1 is a gate node, the second node N2 is a source node, and the third node N3 is a drain node in the driving transistor T1, as an example.

The light emitting device ED may include an anode electrode 200, an organic layer 330, and a cathode electrode 340. The anode electrode 200 may be a pixel electrode disposed in each subpixel SP, and may be electrically connected to the second node N2 of the driving transistor T1 of each subpixel SP. The cathode electrode 340 may be a common electrode commonly disposed in the plurality of subpixels SP, and a base voltage VSS may be applied thereto.

Alternatively, the anode electrode 200 may be a common electrode, and the cathode electrode 340 may be a pixel electrode. Hereinafter, for convenience of explanation, it is assumed that anode electrode 200 is a pixel electrode and the cathode electrode 340 is a common electrode.

The light emitting device ED may have a specific emission area, and the number of emission areas may be one or more, as will be described later.

The light emitting device ED may be an organic light emitting diode (OLED), an inorganic light emitting diode, or a quantum dot light emitting device. In the case that the light emitting device ED is an organic light emitting diode, the organic layer 330 in the light emitting device ED may include an organic light emitting layer containing an organic material.

The scan transistor T2 may be controlled on-off by a scan signal SCAN, which is a gate signal applied through a gate line GL, and the scan transistor T2 may be electrically connected between the first node N1 of the driving transistor T1 and the data line DL. The storage capacitor Cst may be electrically connected between the first node N1 and the second node N2 of the driving transistor T1.

The subpixel circuit unit may have a 2T1C structure including two transistors DT and ST and one capacitor Cst, and in some cases, may further include one or more transistors. Alternatively, the subpixel circuit unit may further include one or more capacitors.

The storage capacitor Cst may be an external capacitor intentionally designed outside the driving transistor T1 rather than a parasitic capacitor (e.g., Cgs, Cgd) which is an internal capacitor existing between the first node N1 and the second node N2 of the driving transistor T1. Each of the driving transistor T1 and the scan transistor T2 may be an n-type transistor or a p-type transistor.

Circuit elements within each subpixel, in particular, light emitting devices EDs implemented with organic light-emitting diodes OLEDs containing organic materials may be vulnerable to external moisture or oxygen. Accordingly, an encapsulation layer 350 may be disposed on the display panel 110 to prevent oxygen from penetrating into the circuit elements (particularly, the light emitting devices ED). The encapsulation layer 350 may be disposed to cover the light emitting device ED.

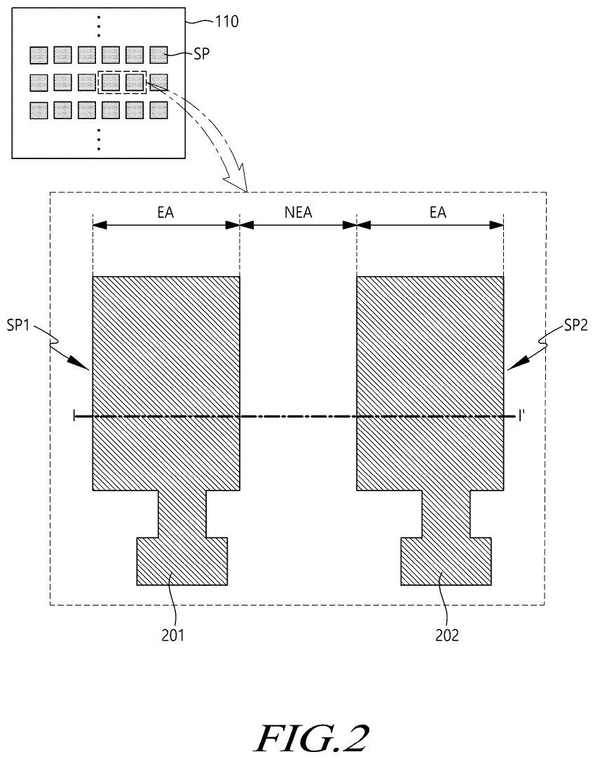

FIG. 2 illustrates an example of a planar structure of a subpixel.

As shown in FIG. 2, a display panel 110 may include a plurality of subpixels SP. The plurality of subpixels SP may include a first subpixel SP1 and a second subpixel SP2. The first subpixel SP1 and the second subpixel SP2 may be one of a red subpixel, a green subpixel, and a blue subpixel, respectively.

Each of the plurality of subpixels SP may include an anode electrode. The anode electrode may include a first anode electrode 201 and a second anode electrode 202. The first anode electrode 201 may be disposed in an area corresponding to the first subpixel SP1, and the second anode electrode 202 may be disposed in an area corresponding to the second subpixel SP2.

The first anode electrode 201 and the second anode electrode 202 may be made of the same or substantially same material, but are not limited thereto.

Each subpixel SP1 and SP2 may include a light emitting area or an emission area EA.

As described above, the emission area EA may be an area where an anode electrode, an organic layer, and a cathode electrode overlap.

The respective emission area EA may be formed in an area where the first anode electrode 201 of the first subpixel SP1 is disposed, and the second anode electrode 202 of the second subpixel SP2 is disposed.

The width of an emission area EA in one direction may be the same as or similar to the width of each anode electrode 201 and 202 in the same direction, but is not limited thereto.

A non-emission area NEA may be an area between the emission area EA of the first subpixel SP1 and the emission area EA of the second subpixel SP2. A circuit for driving a light emitting device may be disposed in the non-emission area NEA.

Each anode electrode 201 and 202 of each subpixel SP1 and SP2 may include a contact hole in an area other than the emission area EA, and may be electrically connected to the driving transistor through the contact hole.

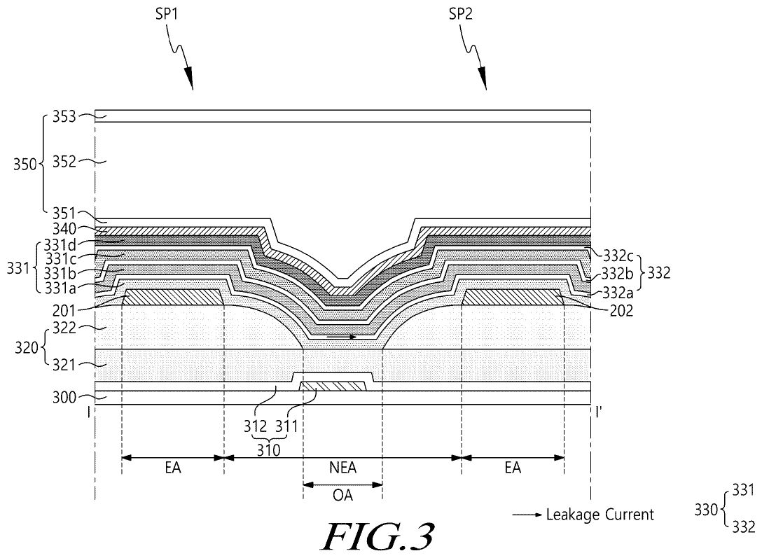

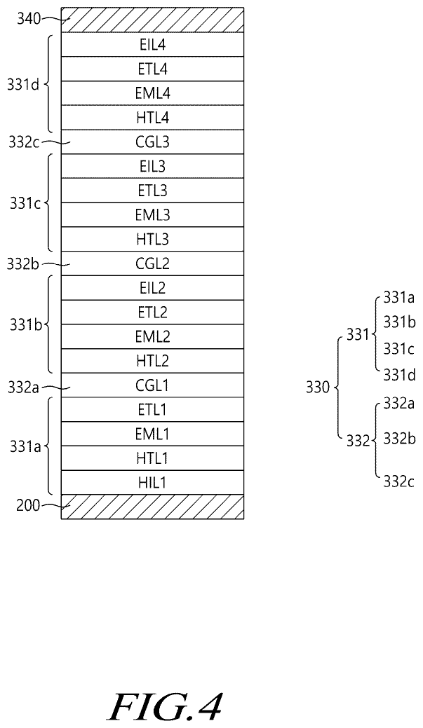

FIG. 3 illustrates an example of the cross-sectional structure of portion II′ of FIG. 2. FIG. 4 illustrates an example of the organic layer shown in FIG. 3.

As shown in FIG. 3, the display device may include a substrate 300 on which a plurality of subpixels SP including a first subpixel SP1 and a second subpixel SP2 are disposed. The substrate 300 may support various components of the display device. The substrate 300 may be made of a flexible plastic material, but is not limited thereto.

A circuit element layer 310 may be disposed on the substrate 300.

The circuit element layer 310 may include various circuit elements for driving subpixels, such as a driving transistor, a sensing transistor, a storage capacitor, a line 311, and a buffer layer 312.

The line 311 may be disposed on the substrate 300, and may be a data line, a driving voltage line, or a sensing line.

The line 311 may be disposed in the non-emission area NEA.

The buffer layer 312 may be disposed on the substrate 300, and may be disposed to cover the line 311. The buffer layer 312 may prevent ions or impurities from diffusing from the substrate 300 and may block moisture penetration. Additionally, the buffer layer 312 may improve surface flatness. The buffer layer 312 may include an inorganic material, such as oxide or nitride, an organic material, or an organic-inorganic composite, and may be formed in a single-layer or multi-layer structure. For example, the buffer layer 312 may have a triple (or more) layer structure composed of silicon oxide, silicon nitride, and silicon oxide.

The circuit element layer 310 may include an active layer (not shown), a gate insulating layer (not shown), and a plurality of electrodes (not shown).

The active layer may be disposed on the buffer layer 312. The active layer may be formed of a silicon-based semiconductor material or an oxide-based semiconductor material. The active layer may include a source area, a drain area, and a channel area between the source area and the drain area.

The gate insulating layer may be disposed on the active layer.

A plurality of electrodes may be disposed on the gate insulating layer. The plurality of electrodes may include a gate electrode, a source electrode, and a drain electrode.

A color filter (not shown) may be disposed on the buffer layer 312. The color filter may be disposed between the buffer layer 312 and a first overcoat layer 321, and may be disposed to overlap the emission area EA of each subpixel SP1 and SP2.

An overcoat layer 320 may be disposed on the buffer layer 312.

The overcoat layer 320 may include a first overcoat layer 321 and a second overcoat layer 322. The overcoat layer 320 may include organic materials, such as polyimide, benzocyclobutene series resin, and acrylate, but is not limited thereto. The overcoat layer 320 may prevent gas generated within the display device from being delivered to the light emitting device ED.

The first overcoat layer 321 may be disposed on the buffer layer 312.

The second overcoat layer 322 may be disposed on the first overcoat layer 321. The second overcoat layer 322 may be disposed to overlap the first subpixel SP1, and may be disposed to overlap the second subpixel SP2.

The second overcoat layer 322 may have an opening area OA in at least some areas on the first overcoat layer 321, for example, in areas that do not overlap the first subpixel SP1 and the second subpixel SP2.

The opening area OA may be formed in the non-emission area NEA. At least a portion of the second overcoat layer 322 may have a curved surface around the opening area OA, but is not limited thereto.

The first anode electrode 201 and the second anode electrode 202 may be disposed on the second overcoat layer 322.

The first anode electrode 201 and the second anode electrode 202 may be made of a transparent conductive material capable of transmitting light. For example, the first anode electrode 201 and the second anode electrode 202 may be formed of at least one of indium tin oxide (ITO) and indium zinc oxide (IZO), however, is not limited thereto.

The first anode electrode 201 may be disposed on the second overcoat layer 322 in an area corresponding to the first subpixel SP1, and the second anode electrode 202 may be disposed on the second overcoat layer 322 in an area corresponding to the second subpixel SP2. The width of the first anode electrode 201 and the second anode electrode 202 may be the same as or similar to the width of the emission area EA, but is not limited thereto. Each anode electrode 201 and 202 may not be disposed in the opening area of the second overcoat layer 322.

The organic layer 330 may be disposed on the first anode electrode 201, the first overcoat layer 321, the second overcoat layer 322, and the second anode electrode 202. The organic layer 330 may include a plurality of intermediate layers 331 and a plurality of charge generation layers 332. The organic layer 330 may be in the form of a plurality of intermediate layers 331 and a plurality of charge generation layers 332 alternately stacked. The structure of FIG. 3 is more simple to manufacture and allows a smaller pixel density.

As illustrated in FIG. 4, the organic layer 330 may be disposed between the anode electrode 200 and the cathode electrode 340.

The plurality of intermediate layers 331 may include a first intermediate layer 331a, a second intermediate layer 331b on the first intermediate layer 331a, a third intermediate layer 331c on the second intermediate layer 331b, and a fourth intermediate layer 331d on the third intermediate layer 331c.

In FIGS. 3 and 4, the organic layer 330 is shown as having four intermediate layers 331, but it is not limited thereto, and the organic layer 330 may include two or three or more intermediate layers 331.

The plurality of charge generation layers 332 may include a first charge generation layer 332a, a second charge generation layer 332b on the first charge generation layer 332a, and a third charge generation layer 332c on the second charge generation layer 332b. In FIGS. 3 and 4, the organic layer 330 is shown as having three charge generation layers 332, but it is not limited thereto, and the organic layer 330 may include one or two charge generation layers 332. For example, the first intermediate layer 331a may be disposed on the anode electrode 200. The first intermediate layer 331a may be formed as a structure in which a first hole injection layer HIL1, a first hole transport layer HTL1, a first emission layer EML1 emitting light of a first color, and a first electron transport layer ETL1 are sequentially stacked, but is not limited thereto. The first emission layer EML1 may be at least one of a red emission layer emitting red light, a green emission layer emitting green light, a blue emission layer emitting blue light, and a yellow emission layer emitting yellow light, but is not limited thereto.

The first charge generation layer 332a may be disposed on the first intermediate layer 331a. The first charge generation layer 332a may be a structure in which an N-type charge generation layer for providing electrons to the first intermediate layer 331a and a P-type charge generation layer for providing holes to the second intermediate layer 331b are stacked.

The second intermediate layer 331b may be disposed on the first charge generation layer 332a. The second intermediate layer 331b may be formed as a structure in which a second hole injection layer HTL2, a second emission layer EML2 emitting light of a second color, a second electron transport layer ETL2, and a second electron injection layer EIL2 are sequentially stacked, but is not limited thereto. The second emission layer EML2 may emit light of a different color than the first emission layer EML1. For example, the first emission layer EML1 may be a blue emission layer that emits blue light, and the second emission layer EML2 may be a yellow emission layer that emits yellow light.

The second charge generation layer 332b may be disposed on the second intermediate layer 331b.

The third intermediate layer 331c may be disposed on the second charge generation layer 332b. The third intermediate layer 331c may be formed as a structure in which a third hole transport layer HTL3, a third emission layer EML3 emitting light of a third color, a third electron transport layer ETL3, and a third electron injection layer EIL3 are sequentially stacked, but is not necessarily limited thereto.

The third charge generation layer 332c may be disposed on the third intermediate layer 331c.

The fourth intermediate layer 331d may be disposed on the third charge generation layer 332c. The fourth intermediate layer 331d may be formed as a structure in which a fourth hole transport layer HTL4, a fourth emission layer EML4 emitting light of a fourth color, a fourth electron transport layer ETL4, and a fourth electron injection layer EIL4 are sequentially stacked, but is not necessarily limited thereto.

A cathode electrode 340 may be disposed on the fourth intermediate layer 331d. The cathode electrode 340 may be a reflective electrode which reflects light, and may be made of an opaque conductive material. For example, the cathode electrode 340 may be formed of at least one of silver (Ag), aluminum (Al), gold (Au), molybdenum (Mo), tungsten (W), chromium (Cr), or alloys thereof, but is not limited thereto.

With reference again to FIG. 3, an encapsulation layer 350 may be disposed on the cathode electrode 340.

The encapsulation layer 350 may prevent moisture or oxygen from penetrating into the light emitting device ED. The encapsulation layer 350 may be formed by an organic encapsulation layer and an inorganic encapsulation layer alternately stacked.

The encapsulation layer 350 may include a first encapsulation layer 351, a second encapsulation layer 352, and a third encapsulation layer 353. Here, the first encapsulation layer 351 and the third encapsulation layer 353 may be inorganic encapsulation layers, and the second encapsulation layer 352 may be an organic encapsulation layer, but are not limited thereto.

In the above-described display device, the organic layer 330 may be disposed to cover both the first subpixel SP1 and the second subpixel SP2, and may cover the entire area between the first subpixel SP1 and the second subpixel SP2. For example, the organic layer 330 may be disposed to extend from the first subpixel SP1 to the second subpixel SP2.

As the organic layer 330 extends from the first subpixel SP1 to the second subpixel SP2, when a data voltage is supplied to the first subpixel SP1 to drive the first subpixel SP1, a part of the current flowing in the first subpixel SP1 may leak and flow into the second subpixel SP2 through the organic layer 330.

In this case, because the charge generation layers 332a, 332b and 332c of the organic layer 330 have low resistance, most of the leaked current may flow along the charge generation layers 332a, 332b and 332c.

Accordingly, even when the second subpixel SP2 is not driven, for example, even when the data voltage is not supplied to the second subpixel SP2, the light may be emitted from the emission area included in the second subpixel SP2 due to leakage current leaked from the first subpixel SP1.

For example, light may be emitted from a subpixel that does not require light emission due to adjacent emitting subpixels, so that there may be difficult to independently control the light emission of each subpixel.

Hereinafter, it will be described a method for blocking, or at least reducing, leakage current flowing between adjacent subpixels with reference to the drawings.

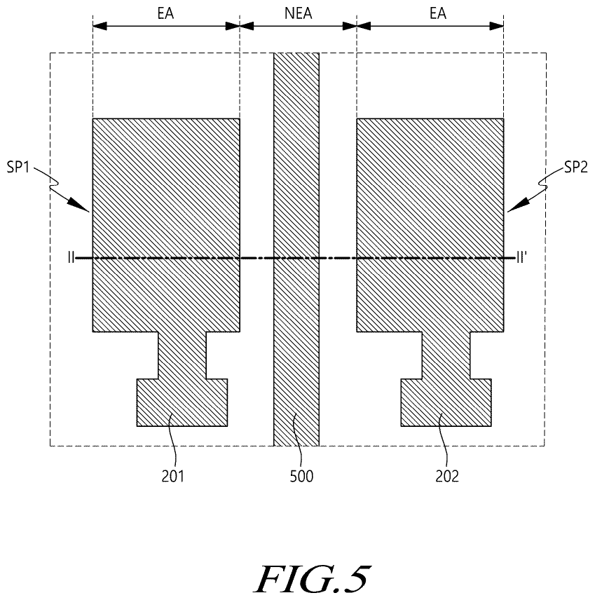

FIG. 5 illustrates another example of a planar structure of a subpixel.

In describing this embodiment, it will be omitted description of components that are substantially the same as or corresponding to the previous embodiment.

As shown in FIG. 5, an auxiliary electrode 500 may be disposed between the first subpixel SP1 and the second subpixel SP2.

For example, the auxiliary electrode 500 may be disposed in the non-emission area NEA. In addition, the auxiliary electrode 500 may be disposed between the first anode electrode 201 and the second anode electrode 202. For example, the auxiliary electrode 500 may not overlap the first anode electrode 201 and the second anode electrode 202.

The auxiliary electrode 500 may be made of the same material as the first anode electrode 201 or the second anode electrode 202. For example, the auxiliary electrode 500 may be made of a transparent conductive material that transmits light. For example, the auxiliary electrode 500 may be formed of at least one of indium tin oxide (ITO) and indium zinc oxide (IZO), but is not limited thereto.

The auxiliary electrode 500 may extend in a direction perpendicular to a direction extending from the first subpixel SP1 to the second subpixel SP2.

In FIG. 5, the auxiliary electrode 500 is shown to be disposed only between the first subpixel SP1 and the second subpixel SP2, but is not limited thereto, and the auxiliary electrode 500 may also be disposed between other adjacent subpixels.

The auxiliary electrode 500 may extend to a non-display area where subpixels are not arranged. However, embodiments are not limited to such.

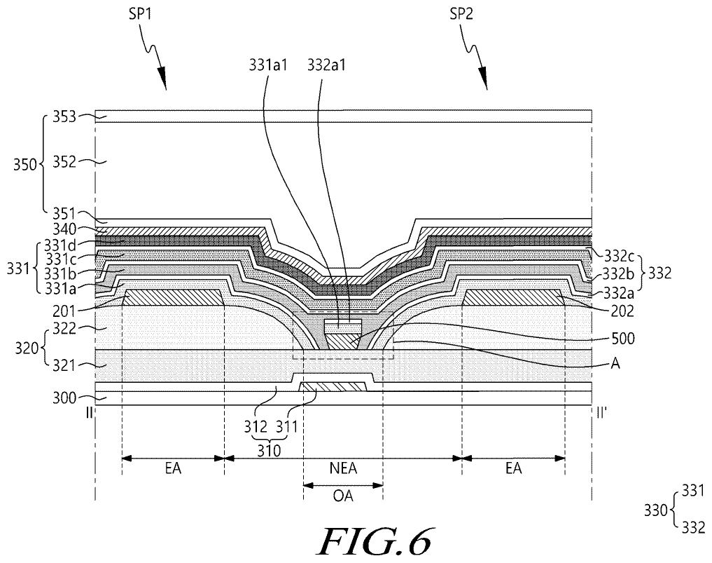

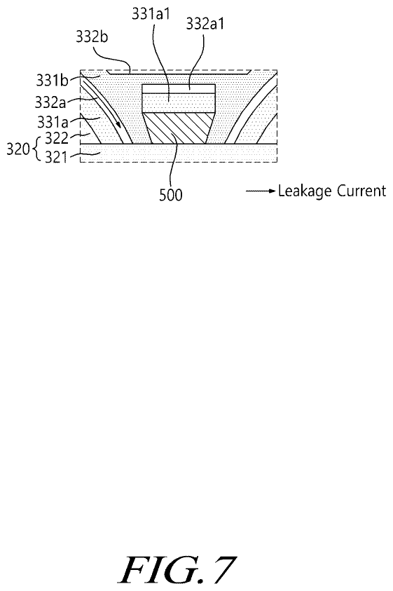

FIG. 6 illustrates an example of the cross-sectional structure of portion II-II′ of FIG. 5. FIG. 7 is an enlarged view of part A of FIG. 6.

In describing this embodiment, it will be omitted description of components that are substantially the same as or corresponding to the previous embodiment.

With reference to FIG. 6, the auxiliary electrode 500 may be disposed on the first overcoat layer 321 in the opening area OA of the second overcoat layer 322.

The first anode electrode 201 and the second anode electrode 202 may be disposed on the second overcoat layer 322 in areas overlapping with the first subpixel SP1 and the second subpixel SP2, respectively. The first anode electrode 201 and the second anode electrode 202 may not be located in the opening area OA of the second overcoat layer 322, but is not limited thereto. Because the first anode electrode 201 and the second anode electrode 202 are located on the second overcoat layer 322, the emission area EA of the first subpixel SP1 and the second subpixel SP2 may overlap the area where the second overcoat layer 322 is disposed.

The auxiliary electrode 500 may be located below the first anode electrode 201 or the second anode electrode 202.

For example, a vertical distance from the auxiliary electrode 500 to the substrate 300 may be smaller than a vertical distance from the first anode electrode 201 or the second anode electrode 202 to the substrate 300.

The area of an upper surface of the auxiliary electrode 500 may be larger than the area of a lower surface. With respect to a plane parallel to the substrate 300, a cross-sectional area of the auxiliary electrode 500 at the upper surface may be larger than a cross-sectional area of the auxiliary electrode 500 at the lower surface. Alternatively, an internal angle between the side surface of the auxiliary electrode 500 and the substrate may be 90 degrees or more. For example, the auxiliary electrode 500 may have an inverted trapezoid shape.

The area of an upper surface of the first anode electrode 201 may be smaller than the area of a lower surface, and the area of the upper surface of the second anode electrode 202 may be smaller than the area of the lower surface. Alternatively, an internal angle formed by the side surface of the first anode electrode 201 or the side surface of the second anode electrode 202 with the substrate may be 90 degrees or less. For example, the first anode electrode 201 and the second anode electrode 202 may each have a trapezoidal shape.

Because the first anode electrode 201 and the second anode electrode 202 have a trapezoidal shape, the organic layer 330 may be not disconnected around the first anode electrode 201 and the second anode electrode 202. For example, when forming the organic layer 330 on the first anode electrode 201 and the second anode electrode 202, the lowest layer of the organic layer 330 may cover both side surfaces of the first anode electrode 201 and the second anode electrode 202.

However, because the auxiliary electrode 500 has an inverted trapezoidal shape, the organic layer 330 may be disconnected, or have a discontinuity, around the auxiliary electrode 500. For example, when forming the organic layer 330 on the auxiliary electrode 500, the lowest layer of the organic layer 330 may not cover the side surface of the auxiliary electrode 500. For example, the organic layer 330 disposed on the auxiliary electrode 500 may be 331a1 or 332a1, which is part of the first intermediate layer 331a or the first charge generation layer 332a.

With further reference to FIGS. 6 and 7, the first intermediate layer 331a and the first charge generation layer 332a may be disconnected around the auxiliary electrode 500.

Because the first intermediate layer 331a is disconnected, a portion of the first intermediate layer 331a may contact an upper surface of the auxiliary electrode 500, but may not contact both side surfaces of the auxiliary electrode 500.

The first intermediate layer 331a may be partially disposed on the second overcoat layer 322. Additionally, at least a portion of the first intermediate layer 331a may be disposed on the first overcoat layer 321.

The first intermediate layer 331a may be in contact with an upper surface of the second overcoat layer 322, and may be in contact with an upper surface of the first overcoat layer 321 in the opening area OA of the second overcoat layer 322.

The first charge generation layer 332a may be disposed on the first intermediate layer 331a along a step of the first intermediate layer 331a.

At least a portion of the first charge generation layer 332a may contact an upper surface of the first overcoat layer 321 in the opening area OA of the second overcoat layer 322.

Because the first charge generation layer 332a is disconnected around the auxiliary electrode 500, the first charge generation layer 332a may not contact either side surfaces of the auxiliary electrode 500. For example, the first charge generation layer 332a may be spaced apart from the auxiliary electrode 500.

In addition, the first charge generation layer 332a may be spaced apart from a portion of the first charge generation layer 332a located on the auxiliary electrode 500.

The second intermediate layer 331b may be disposed on the first charge generation layer 332a. The second intermediate layer 331b may fill the space between the first charge generation layer 332a and the auxiliary electrode 500.

As the second intermediate layer 331b fills the space between the first charge generation layer 332a and the auxiliary electrode 500, the second intermediate layer 331b may contact both side surfaces of the auxiliary electrode 500. In addition, the second intermediate layer 331b may cover a portion of the first intermediate layer 331a and a portion of the first charge generation layer 332a located on an upper surface of the auxiliary electrode 500.

With reference to FIG. 7, because the first charge generation layer 332a is not continuous, around the auxiliary electrode 500, the current leaked from the first subpixel SP1 may not reach the second subpixel SP2.

As described above, because the first charge generation layer 332a has a small resistance, most of the leakage current flowing from the first subpixel SP1 to the second subpixel SP2 through the organic layer 330 may be transferred through the first charge generation layer 332a. Accordingly, when the first charge generation layer 332a is not continuous as described above, it is possible to block, or at least to reduce, the leakage current flowing between adjacent subpixels.

In addition, in FIGS. 6 and 7, only the first intermediate layer 331a and the first charge generation layer 332a are shown to be disconnected (not continuous), but is not limited thereto. The second intermediate layer 331b, the second charge generation layer 332b, the third intermediate layer 331c, the third charge generation layer 332c, and the fourth intermediate layer 331d may be all disconnected (not continuous), or the third intermediate layer 331c and the third charge generation layer 332c may be disconnected (not continuous), or the second intermediate layer 331b and the second charge generation layer 332b may be disconnected (not continuous), or any combination of first, second, third and/or fourth intermediate layers, and/or first, second and and/or third charge generation layers may be disconnected (not continuous).

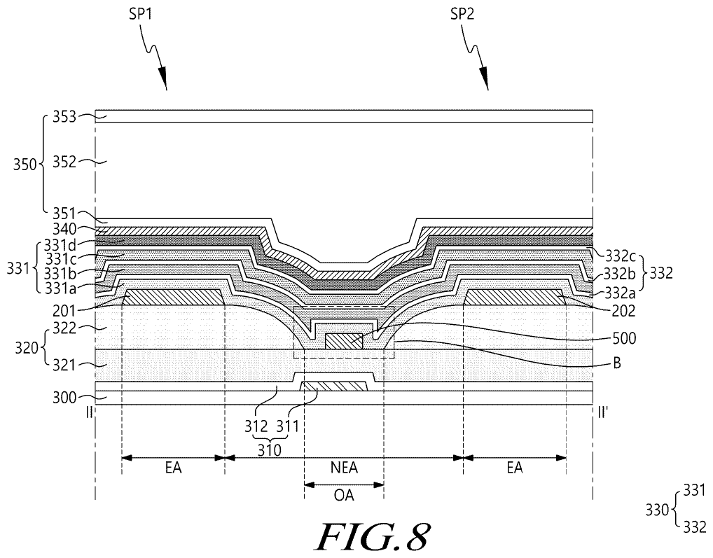

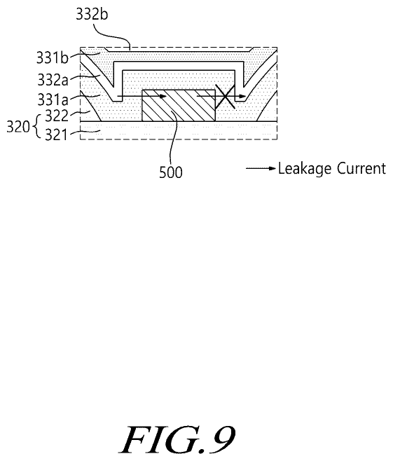

FIG. 8 illustrates another example of the cross-sectional structure of portion II-II′ of FIG. 5. FIG. 9 is an enlarged view of part B of FIG. 8.

In describing this embodiment, it will be omitted description of components that are substantially the same as or corresponding to the previous embodiment.

As shown in FIG. 8, the auxiliary electrode 500 may be located within the opening area OA of the second overcoat layer 322.

The auxiliary electrode 500 may be disposed on the first overcoat layer 321 between the first subpixel SP1 and the second subpixel SP2.

The area of the upper surface of the auxiliary electrode 500 may be equal to the area of the lower surface. With respect to a plane parallel to the substrate 300, a cross-sectional area of the auxiliary electrode 500 at the upper surface may be substantially the same as a cross-sectional area of the auxiliary electrode 500 at the lower surface. Alternatively, the angle between the side surface of the auxiliary electrode 500 and the substrate may be 90 degrees. For example, the auxiliary electrode 500 may have a rectangular shape.

Because the auxiliary electrode 500 has a rectangular shape, the organic layer 330 may not be disconnected (may be continuous) around the auxiliary electrode 500. For example, when forming the organic layer 330 on the auxiliary electrode 500, the lowest layer of the organic layer 330 may cover all side surfaces of the auxiliary electrode 500.

With further reference to FIGS. 8 and 9, the first intermediate layer 331a may cover all of the auxiliary electrodes 500.

The first intermediate layer 331a may be partially disposed on the second overcoat layer 322. Additionally, at least a portion of the first intermediate layer 331a may be disposed on the first overcoat layer 321. The first intermediate layer 331a may be in contact with the upper surface of the second overcoat layer 322, and may be in contact with the upper surface of the first overcoat layer 321 in the opening area OA of the second overcoat layer 322.

In addition, the first intermediate layer 331a may contact both the upper surface and both side surfaces of the auxiliary electrode 500.

The first charge generation layer 332a may be disposed on the first intermediate layer 331a along a step of the first intermediate layer 331a.

With reference to FIG. 9, because the first intermediate layer 331a is in contact with the side surface of the auxiliary electrode 500, and the first charge generation layer 332a is disposed on the first intermediate layer 331a, a part of the current which leaks from the first subpixel SP1 and flows through the first charge generation layer 332a may pass through the first intermediate layer 331a and may flow to the auxiliary electrode 500 through the side surface of the auxiliary electrode 500.

As will be described later, because the auxiliary electrode 500 may be electrically connected to the cathode electrode 340 and receive a base voltage, the current flowing through the auxiliary electrode 500 may not flow back to the first charge generation layer 332a and may be removed in the middle as shown in FIG. 9.

Therefore, it is possible to block, or at least to reduce, the leakage current flowing from the first subpixel SP1 to the second subpixel SP2.

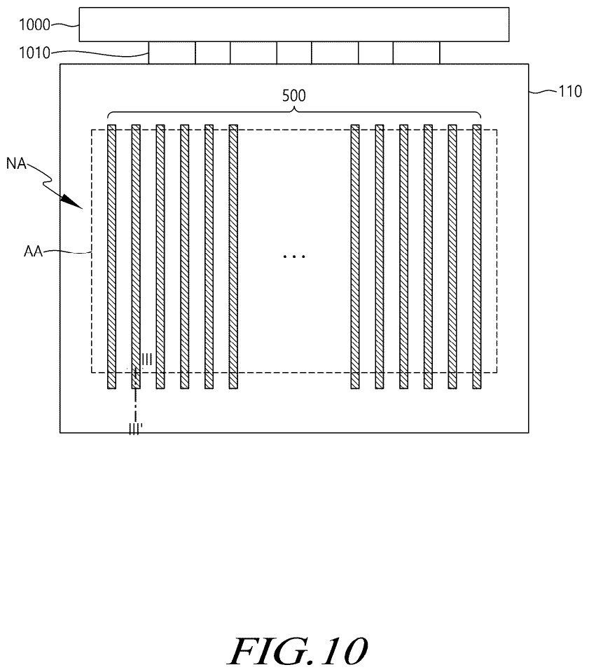

FIG. 10 illustrates an example of a planar structure of a display panel according to embodiments of the present disclosure.

As illustrated in FIG. 10, a display panel 110 may be connected to a data driver 1000. The data driver 1000 is a circuit for driving a plurality of data lines, and may output data signals through the plurality of data lines.

The data driver 1000 may receive digital image data DATA from a timing controller, convert the received image data DATA into an analog data signal, and output to a plurality of data lines.

In FIG. 10, the data driver 1000 is illustrated to be connected to the display panel 110 through a film 1010 in a chip-on-film (COF) method, but is not limited thereto. The data driver 1000 may be connected to the display panel 110 using a tape automated bonding (TAB) method, or may be connected to a bonding pad of the display panel 110 using a chip-on-glass (COG) method or a chip-on-panel (COP) method.

The plurality of auxiliary electrodes 500 may be disposed to at least partially overlap the display area AA of the display panel 110.

The display area AA may refer to an area where a plurality of subpixels SP are arranged. The auxiliary electrodes 500 may be disposed between a plurality of subpixels SP within the display area AA. The auxiliary electrodes 500 may overlap with a data line or a reference voltage line, but are not limited thereto.

A non-display area NA may surround the display area AA outside the display area AA.

A part of the auxiliary electrodes 500 may be disposed in the non-display area NA. However, embodiments are not limited thereto, and the auxiliary electrodes 500 may be disposed only within the display area AA. The auxiliary electrodes 500 may be electrically connected to the cathode electrode in the non-display area NA.

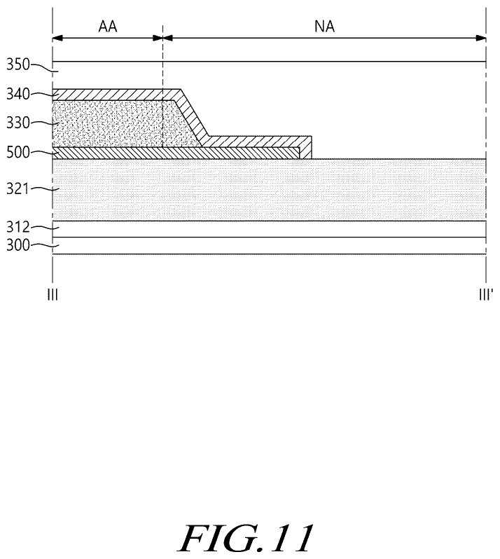

FIG. 11 illustrates an example of the cross-sectional structure of portion III-III′ of FIG. 10.

As shown in FIG. 11, a buffer layer 312 may be disposed on the substrate 300, a first overcoat layer 321 may be disposed on the buffer layer 312, and the auxiliary electrode 500 may be disposed on the first overcoat layer 321.

An organic layer 330 and a cathode electrode 340 may be disposed on the auxiliary electrode 500.

In the display area AA, the organic layer 330 may be disposed on the auxiliary electrode 500.

The organic layer 330 may include a plurality of intermediate layers 331 and a plurality of charge generation layers 332, as described above. The organic layer 330 may be partially disposed in the non-display area NA. The cathode electrode 340 may be disposed on the organic layer 330.

In the display area AA, the cathode electrode 340 may be separated from the auxiliary electrode 500. The organic layer 330 may be disposed between the cathode electrode 340 and the auxiliary electrode 500 in the display area AA.

In at least a portion of the non-display area NA, the cathode electrode 340 may be electrically connected to the auxiliary electrode 500.

In at least a portion of the non-display area NA, an upper surface of the auxiliary electrode 500 may contact a lower surface of the cathode electrode 340. However, the present embodiment is not limited thereto, and the cathode electrode 340 may be electrically connected to the auxiliary electrode 500 in the display area AA.

The base voltage may be supplied to the cathode electrode 340. Because the cathode electrode 340 is electrically connected to the auxiliary electrode 500, the auxiliary electrode 500 may receive the base voltage. For example, leakage current generated in at least one subpixel may be removed by the auxiliary electrode 500 disposed adjacent to the subpixel.

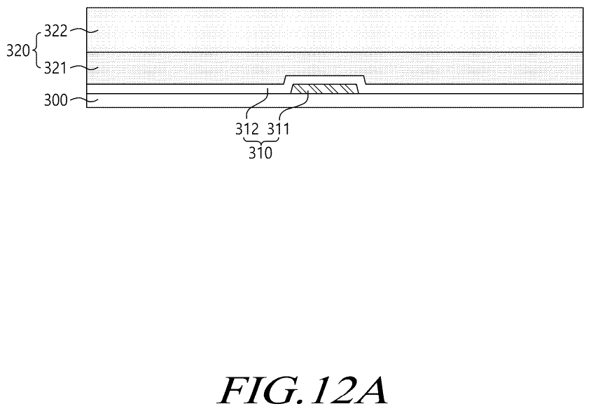

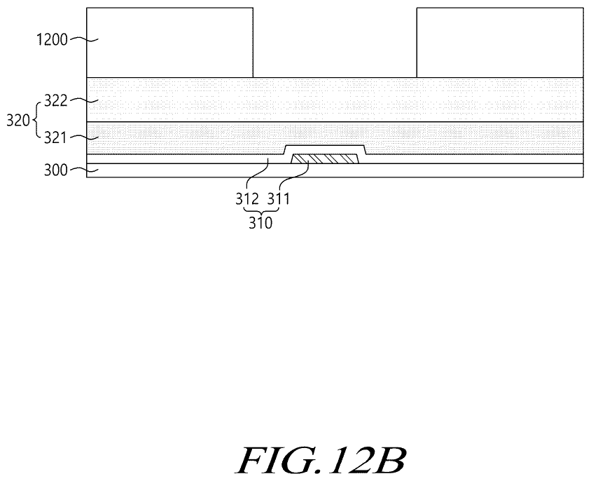

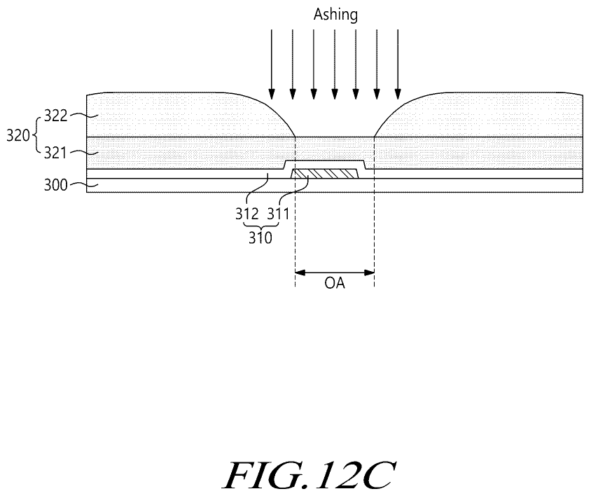

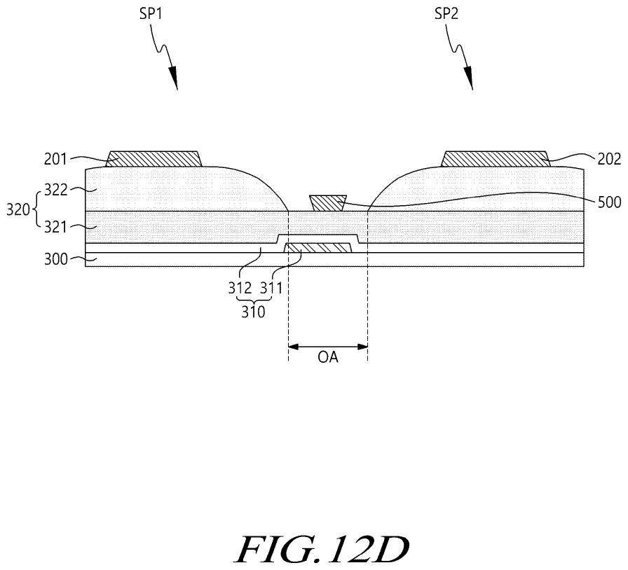

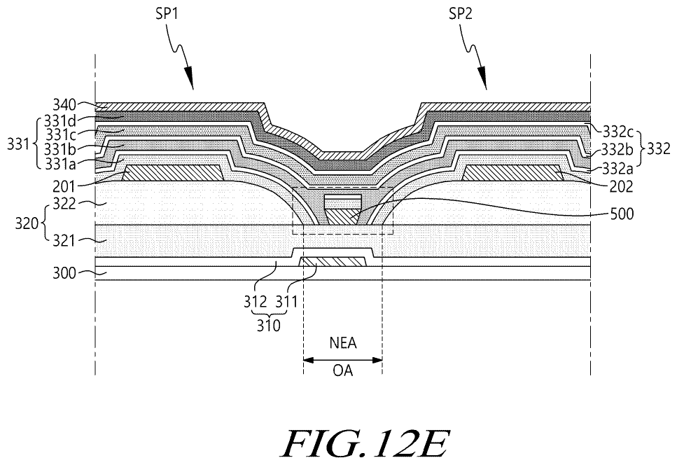

FIGS. 12A to 12E illustrate examples of methods for manufacturing a display device according to embodiments of the present disclosure.

As shown in FIG. 12A, a line 311 and a buffer layer 312 may be formed on a substrate 300, a first overcoat layer 321 may be formed on the buffer layer 312, and a second overcoat layer 322 may be formed on the first overcoat layer 321.

Here, the first overcoat layer 321 may be made of a hydrophilic material, and the second overcoat layer 322 may be made of a hydrophobic material. However, the present embodiment is not limited thereto, and the second overcoat layer 322 may be made of a hydrophilic material.

In the case that the second overcoat layer 322 is made of a hydrophilic material, a surface of the second overcoat layer 322 may be modified by plasma treatment using hydrogen (H2) gas. If the plasma treatment is performed on the upper surface of the second overcoat layer 322, a thin hydrophobic film may be formed on the upper surface of the second overcoat layer 322.

With reference to FIG. 12B, a photoresist (PR) 1200 may be formed on the second overcoat layer 322.

The photoresist 1200 may expose at least a portion of the upper surface of the second overcoat layer 322.

With reference to FIG. 12C, the second overcoat layer 322 disposed in the area where the photoresist 1200 is not formed may be etched through an ashing process, and the photoresist 1200 may be removed.

Accordingly, an opening area OA may be formed in at least a portion of the first overcoat layer 321. The opening area OA may be an area between adjacent subpixels, for example, an area included in a non-emission area, but is not limited thereto.

As shown in FIG. 12D, the first anode electrode 201 and the second anode electrode 202 may be formed on the second overcoat layer 322. The first anode electrode 201 may correspond to the first subpixel SP1, and the second anode electrode 202 may correspond to the second subpixel SP2.

Because the first anode electrode 201 and the second anode electrode 202 are formed on the second overcoat layer 322 made of a hydrophobic material, they may be better bonded to the second overcoat layer 322 by a hydrophobic bond. Accordingly, during the etching process, the etchant may not penetrate between the first anode electrode 201 and the second overcoat layer 322 or between the second anode electrode 202 and the second overcoat layer 322, so that the upper portions of the first anode electrode 201 and the second anode electrode 202 may be etched more than the lower portions.

Therefore, the size of the upper surface of the first anode electrode 201 and the second anode electrode 202 may be smaller than the size of the lower surface. Alternatively, the internal angle formed by each side surface of the first anode electrode 201 and the side surface of the second anode electrode 202 with the substrate 300 may be less than 90 degrees.

An auxiliary electrode 500 may be formed on the first overcoat layer 321 in the opening area OA.

The auxiliary electrode 500 may be formed using the same mask as a mask forming the first anode electrode 201 and the second anode electrode 202. The auxiliary electrode 500 may be made of the same material as the first anode electrode 201 and the second anode electrode 202, however, is not limited thereto.

Here, the first overcoat layer 321 may be made of a hydrophilic material. The auxiliary electrode 500 formed on the first overcoat layer 321 in the opening area OA does not form a hydrophobic bond with the first overcoat layer 321, and therefore may be not sufficiently bonded with the first overcoat layer 321. Accordingly, during the etching process, the etchant may easily penetrate between the auxiliary electrode 500 and the first overcoat layer 321, so the lower portion of the auxiliary electrode 500 may be etched more than the upper portion.

Therefore, the size of the upper surface of the auxiliary electrode 500 may be larger than the size of the lower surface. Alternatively, the angle formed by the side surface of the auxiliary electrode 500 and the substrate 300 may be 90 degrees or more.

With reference to FIG. 12E, an organic layer 330 may be formed on the first anode electrode 201, the second anode electrode 202, and the auxiliary electrode 500. Because the size of the upper surface of the first anode electrode 201 and the second anode electrode 202 is smaller than the size of the lower surface, when the organic layer 330 is formed, the organic layer 330 may not be disconnected around the area where the first anode electrode 201 and the second anode electrode 202 are disposed.

However, because the size of the upper surface of the auxiliary electrode 500 is larger than the size of the lower surface, when the organic layer 330 is formed, at least a portion of the organic layer 330 may be disconnected around the area where the auxiliary electrode 500 is disposed.

For example, as shown in FIG. 12E, the first intermediate layer 331a and the first charge generation layer 332a may be disconnected around the auxiliary electrode 500, but is not limited thereto. In addition, the second intermediate layers 331b to fourth intermediate layers 331d, the second charge generation layer 332b, and the third charge generation layer 332c may be also disconnected around the auxiliary electrode 500, or any combination of first, second, third and/or fourth intermediate layers, and/or first, second and/or third charge generation layers may be disconnected (not continuous) around the auxiliary electrode 500.

In an embodiment according to the present disclosure, at least one of the first charge generation layer 332a, the second charge generation layer 332b, and the third charge generation layer 332c may be disconnected around the auxiliary electrode 500, so that the leakage current which leaks from the first subpixel SP1 or the second subpixel SP2 and flows along each charge generation layer may not flow to adjacent subpixels and may be blocked or at least reduced.

The embodiments of the present disclosure described above are briefly described as follows.

According to an embodiment of the present disclosure, there may provide a display device including a substrate, a first overcoat layer on the substrate, a second overcoat layer on the first overcoat layer and defining at least one open area at which the overcoat layer is absent, an anode electrode on the second overcoat layer, an organic layer on the first overcoat layer, the second overcoat layer, and the anode electrode, and an auxiliary electrode in the at least one open area and on the first overcoat layer to be between the first overcoat layer. The auxiliary electrode may have an upper surface larger than or equal to a lower surface of the auxiliary electrode.

In the display device according to an embodiment of the present disclosure, the organic layer may contact an upper surface of the second overcoat layer.

In the display device according to an embodiment of the present disclosure, at least a portion of the organic layer may contact at least a portion of a side surface of the auxiliary electrode.

In the display device according to an embodiment of the present disclosure, the organic layer may include a first charge generation layer and a second charge generation layer on the first charge generation layer, and the first charge generating layer may be disconnected around the auxiliary electrode.

In the display device according to an embodiment of the present disclosure, the organic layer may include a first intermediate layer and a second intermediate layer on the first intermediate layer, and at least a portion of the second intermediate layer may contact at least a portion of a side surface of the auxiliary electrode.

In the display device according to an embodiment of the present disclosure, the organic layer may include a first intermediate layer and a second intermediate layer on the first intermediate layer, and at least a portion of the first intermediate layer may contact at least a portion of a side surface of the auxiliary electrode.

In the display device according to an embodiment of the present disclosure, the substrate may includes a display area where a subpixel is disposed and a non-display area around the display area. The display device may further include a cathode electrode disposed separately from the auxiliary electrode in the display area, and electrically connected to at least a portion of the auxiliary electrode in the non-display area.

In the display device according to an embodiment of the present disclosure, a vertical distance from the auxiliary electrode to the substrate may be smaller than a vertical distance from the anode electrode to the substrate.

In the display device according to an embodiment of the present disclosure, the anode electrode may be disposed in an area other than the open area.

According to an embodiment of the present disclosure, a display device including at least a first subpixel and a second subpixel, may comprise a substrate, a first overcoat layer on the substrate, a second overcoat layer on at least a portion of the first overcoat layer, a first anode electrode on the second overcoat layer and overlapping the first subpixel, a second anode electrode on the second overcoat layer and overlapping the second subpixel, an organic layer on the first overcoat layer, the second overcoat layer, the first anode electrode, and the second anode electrode, and an auxiliary electrode on the first overcoat layer between the first overcoat layer and the organic layer, and, in a plan view, between the first anode electrode and the second anode electrode. A first angle between the substrate and a side surface of the auxiliary electrode may be different than a second angle between the substrate and a side surface of at least one of the first anode electrode or second anode electrode.

In the display device according to an embodiment of the present disclosure, the first angle may be greater than the second angle.

In the display device according to an embodiment of the present disclosure, the organic layer may contact an upper surface of the second overcoat layer.

In the display device according to an embodiment of the present disclosure, at least a portion of the organic layer may contact at least a portion of a side surface of the auxiliary electrode.

In the display device according to an embodiment of the present disclosure, the organic layer may include a first charge generation layer and a second charge generation layer on the first charge generation layer, and the first charge generating layer may be disconnected around the auxiliary electrode.

In the display device according to an embodiment of the present disclosure, the organic layer may include a first intermediate layer and a second intermediate layer on the first intermediate layer, and at least a portion of the first intermediate layer may contact at least a portion of a side surface of the auxiliary electrode.

According to an embodiment of the present disclosure, there may provide a display device including a substrate, a first overcoat layer on the substrate, a second overcoat layer on the first overcoat layer and defining at least one open area at which the second overcoat layer is absent, an auxiliary electrode on the first overcoat layer and in the at least one open area, and an organic layer on the auxiliary electrode, at least a portion of the organic layer contacting both side surfaces of the auxiliary electrode.

In the display device according to an embodiment of the present disclosure, the organic layer may include a first intermediate layer and a second intermediate layer on the first intermediate layer, and at least a portion of the second intermediate layer may contact at least a portion of both side surfaces of the auxiliary electrode.

In the display device according to an embodiment of the present disclosure, the organic layer may include a first intermediate layer and a second intermediate layer on the first intermediate layer, and at least a portion of the first intermediate layer may contact at least a portion of both side surfaces of the auxiliary electrode.

In the display device according to an embodiment of the present disclosure, an angle formed between the side surface of the auxiliary electrode and the substrate may be greater than an angle formed between the side surface of the first anode electrode or the side surface of the second anode electrode and the substrate.

In the display device according to an embodiment of the present disclosure, with respect to a plane parallel to an upper surface of the substrate, a cross-sectional area of the auxiliary electrode at an upper surface thereof may be larger than or equal to a cross-sectional area of the auxiliary electrode at the lower surface thereof.

In the display device according to an embodiment of the present disclosure, the auxiliary electrode may have an upper surface larger than or equal to a lower surface of the auxiliary electrode.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display device, comprising:
a substrate;
a first overcoat layer on the substrate;
a second overcoat layer on the first overcoat layer, the second overcoat layer defining at least one open area at which the second overcoat layer is absent;
an anode electrode on the second overcoat layer;
an organic layer on the first overcoat layer, the second overcoat layer, and the anode electrode; and
an auxiliary electrode in the at least one open area and on the first overcoat layer to be between the first overcoat layer and the organic layer,
wherein the auxiliary electrode has an upper surface larger than or equal to a lower surface of the auxiliary electrode.

2. The display device of claim 1, wherein the organic layer contacts an upper surface of the second overcoat layer.

3. The display device of claim 1, wherein at least a portion of the organic layer contacts at least a portion of a side surface of the auxiliary electrode.

4. The display device of claim 1, wherein the organic layer includes a first charge generation layer and a second charge generation layer on the first charge generation layer, and
wherein the first charge generating layer is disconnected around the auxiliary electrode.

5. The display device of claim 1, wherein the organic layer includes a first intermediate layer and a second intermediate layer on the first intermediate layer, and
wherein at least a portion of the second intermediate layer contacts at least a portion of a side surface of the auxiliary electrode.

6. The display device of claim 1, wherein the organic layer includes a first intermediate layer and a second intermediate layer on the first intermediate layer, and
wherein at least a portion of the first intermediate layer contacts at least a portion of a side surface of the auxiliary electrode.

7. The display device of claim 1, wherein the substrate includes a display area where a subpixel is disposed and a non-display area around the display area, and
wherein the display device further comprises a cathode electrode disposed separately from the auxiliary electrode in the display area, and electrically connected to at least a portion of the auxiliary electrode in the non-display area.

8. The display device of claim 1, wherein a vertical distance from the auxiliary electrode to the substrate is smaller than a vertical distance from the anode electrode to the substrate.

9. The display device of claim 1, wherein the anode electrode is in an area other than the open area.

10. A display device including at least a first subpixel and a second subpixel, the display device comprising:
a substrate;
a first overcoat layer on the substrate;
a second overcoat layer on at least a portion of the first overcoat layer;
a first anode electrode on the second overcoat layer and overlapping the first subpixel;
a second anode electrode on the second overcoat layer and overlapping the second subpixel;
an organic layer on the first overcoat layer, the second overcoat layer, the first anode electrode, and the second anode electrode; and
an auxiliary electrode on the first overcoat layer between the first overcoat layer and the organic layer, and in a plan view, between the first anode electrode and the second anode electrode,
wherein a first angle between the substrate and a side surface of the auxiliary electrode is different than a second angle between the substrate and a side surface of at least one of the first anode electrode or second anode electrode.

11. The display device of claim 10, wherein the first angle is greater than the second angle.

12. The display device of claim 10, wherein the organic layer contacts an upper surface of the second overcoat layer.

13. The display device of claim 10, wherein at least a portion of the organic layer contacts at least a portion of a side surface of the auxiliary electrode.

14. The display device of claim 10, wherein the organic layer includes a first charge generation layer and a second charge generation layer on the first charge generation layer, and
wherein the first charge generating layer is disconnected around the auxiliary electrode.

15. The display device of claim 10, wherein the organic layer includes a first intermediate layer and a second intermediate layer on the first intermediate layer, and
wherein at least a portion of the first intermediate layer contacts at least a portion of a side surface of the auxiliary electrode.

16. A display device, comprising:
a substrate;
a first overcoat layer on the substrate;
a second overcoat layer on the first overcoat layer, the second overcoat layer defining at least one open area at which the second overcoat layer is absent;
an auxiliary electrode on the first overcoat layer and in the at least one open area; and
an organic layer on the auxiliary electrode, at least a portion of the organic layer contacting both side surfaces of the auxiliary electrode.

17. The display device of claim 16, wherein the organic layer includes a first intermediate layer and a second intermediate layer on the first intermediate layer, and
wherein at least a portion of the second intermediate layer contacts at least a portion of both side surfaces of the auxiliary electrode.

18. The display device of claim 16, wherein the organic layer includes a first intermediate layer and a second intermediate layer on the first intermediate layer, and
wherein at least a portion of the first intermediate layer contacts at least a portion of both side surfaces of the auxiliary electrode.

19. The display device of claim 16, wherein, with respect to a plane parallel to an upper surface of the substrate, a cross-sectional area of the auxiliary electrode at an upper surface thereof is larger than or equal to a cross-sectional area of the auxiliary electrode at the lower surface thereof.

20. The display device of claim 16, wherein the auxiliary electrode has an upper surface larger than or equal to a lower surface of the auxiliary electrode.
